(19) United States
(12) Patent Application Publication
(10) Pub. No.: US 2007/0177427 A1
(43) Pub. Date: Aug. 2, 2007

(54) Nonvolatile memory device and method thereof

(75) Inventors: Geon-Woo Park, Suwon-si (KR); Geum-Jong Bae, Suwon-si (KR); In-Wook Cho, Yongin-si (KR); Byoung-Jin Lee, Seoul (KR); Myung-Yoon Um, Seoul (KR); Sang-Chul Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/698,071

(22) Filed: Jan. 26, 2007

(30) Foreign Application Priority Data
Jan. 27, 2006 (KR) 10-2006-0009061

(51) Int. Cl. G11C 16/04

(52) U.S. Cl. 365/185.18

(57) ABSTRACT

A nonvolatile memory device and method thereof are provided. The example method may include applying a first bias voltage to a gate electrode, applying a second bias voltage to a substrate to obtain a first voltage potential difference between the gate electrode and the substrate and applying a third bias voltage to a first impurity region to obtain a second voltage potential difference between the substrate and the first impurity region, the first and third bias voltages being positive and the second bias voltage being negative. The example nonvolatile memory device may include a gate electrode receiving a first bias voltage, a substrate receiving a second bias voltage, the first and second bias voltages forming a first voltage potential difference between the gate electrode and the substrate and a first impurity region receiving a third bias voltage, the second and third bias voltages forming a second voltage potential difference between the first impurity region and the substrate, the first and third bias voltages being positive and the second bias voltage being negative.

This application claims the priority of Korean Patent Application No. 10-2006-0009061, filed on Jan. 27, 2006, in the Korean Intellectual Property Office, the disclosure of which is incorporated herein in its entirety by reference.

### BACKGROUND OF THE INVENTION

1. Field of the Invention

Example embodiments of the present invention relate generally to a nonvolatile memory device and method thereof, and more particularly to a nonvolatile memory device and method of programming the nonvolatile memory device.

2. Description of the Related Art

Nonvolatile memory devices may be storage devices that may retain data even with the power turned off. Examples of nonvolatile memory devices may include ferroelectric random access memories (FRAMs), erasable and programmable read-only memories (EPROMs) and electrically erasable and programmable ROMs (EEPROMs). EEPROMs may store data by changing threshold voltages of memory cells included therein based on whether the memory cells are charged. Flash memory may be a form of EEPROM which erases data stored in an array of memory cells in block units. Flash memory devices may be deployed within memory cards and/or portable electronic devices.

Flash memory devices may be classified as one of floating gate-type flash memory devices and charge trap-type flash memory devices. Floating gate-type flash memory devices may include floating gates, formed between dielectric layers, which may accumulate electric charges. Charge trap-type flash memory devices may include charge trap layers, formed between dielectric layers, which may accumulate electric charges. Because floating gate-type flash memory devices may accumulate electric charges on floating gates formed of polysilicon layers, even a relatively small defect in tunneling oxide layers included therein may affect an operation of the conventional floating gate-type flash memory devices. In other words, if there is a defect in one or more tunneling oxide layers, floating gate-type flash memory devices may have difficulty retaining data. In addition, defects may limit a degree of cell size reduction (e.g., thereby increasing the difficulty of increasing memory density or reducing a size of the flash memory device), and a higher voltage may be required to program and erase memory cells.

Conventional charge trap-type flash memory devices may include silicon nitride layers as charge trap layers. Electric charges trapped by the charge trap layers may be generally stable because silicon nitride layers may typically include non-conductive material. Thus, charge trap-type flash memory devices may be less affected by defects in tunneling oxide layers. In addition, “vertical” thicknesses of charge trap-type flash memory devices may be reduced more than those of floating gate-type flash memory devices, which may contribute to increased integration density. Charge trap-type flash memory devices may be classified into silicon-oxide-nitride-oxide-silicon (SONOS) flash memory devices or metal-oxide-nitride-oxide-silicon (MONOS) flash memory devices, based upon a material forming a gate electrode therein.

FIG. 1 is a cross-section of a conventional SONOS nonvolatile memory device. Referring to FIG. 1, a gate stack 110 may be formed on a semiconductor substrate 100 with a first conductivity. In addition, first and second impurity regions 121 and 125 for a drain and a source, respectively, each having a second conductivity (e.g., opposite to the first conductivity of the semiconductor substrate 100), may be formed in the semiconductor substrate 100. The gate stack 110 may include a tunneling oxide layer 111, a charge trap layer 113, a charge blocking layer 115 and a control gate electrode 117. The charge trap layer 113 may have a charge trap site with a given density. The charge blocking layer 115 may block or reduce electric charges from moving to the control gate electrode 117 from the charge trap layer 113 (e.g., if the electric charges are trapped in the charge trap layer 113). A channel region 123 may be formed in a portion of the semiconductor substrate 100 between the first and second impurity regions 121 and 125 under the gate stack 110.

Referring to FIG. 1, to program a memory cell, a given bias voltage for programming memory cells (e.g., a positive bias voltage), may be applied to the control gate electrode 117, and a given program voltage may be applied to the first and second impurity regions 121 and 125. “Hot” electrons may be generated in the channel region 123 near the second impurity region 125. The hot electrons may be injected into the charge trap layer 113 via the tunneling oxide layer 111, thereby changing a threshold voltage of the memory cell.

Referring to FIG. 1, to erase the memory cell, a given bias voltage for erasing memory cells (e.g., a negative bias voltage), may be applied to the control gate electrode 117, and a given erase voltage may be applied to the first and second impurity regions 121 and 125. Holes generated in the channel region 123 near the second impurity region 125 may be injected into the charge trap layer 113 via the tunneling oxide layer 111. The holes injected into the charge trap layer 113 may be recombined with the hot electrons trapped in a trap site of the charge trap layer 113. Accordingly, the threshold voltage of the memory cell may be adjusted.

Referring to FIG. 1, because the conventional SONOS nonvolatile memory device may include an oxide-nitride-oxide (ONO) layer constituting the tunneling oxide layer 111, the charge trap layer 113, and the charge blocking layer 115 on an entire surface of the channel region 123, an effective thickness of a gate insulating layer may increase. As the effective thickness of the gate insulating layer increases, the conventional SONOS nonvolatile memory device may have a higher initial threshold voltage and a higher program current. In addition, because the hot electrons trapped in the trap site of the charge trap layer 113 may move in a horizontal direction in the charge trap layer 113, the memory cell may not be completely erased, or at least a longer time may be required to erase the memory cell.

In a conventional “local” SONOS nonvolatile memory device, a charge trap layer may overlap with a control gate electrode. Thus, if a positive bias voltage is applied to the control gate electrode, thereby creating a potential difference between a source region and a drain region, hot electrons generated in a channel region near the drain region may be injected into the charge trap layer by channel hot electron injection (CHEI). The hot electrons injected into the charge trap layer may be trapped in a trap site, and a threshold voltage of a memory cell may be adjusted accordingly. Alternatively, if a negative bias voltage is applied to the control gate electrode to erase the memory cell, thereby creating a potential difference between the source region and the drain region, holes generated in the channel region near the drain region may be injected into the local charge trap layer and may be recombined with the hot electrons trapped in the charge trap layer. Accordingly, the threshold voltage of the memory cell may be adjusted.

In conventional local SONOS nonvolatile memory devices, a higher program voltage may be applied to the control gate electrode to enhance programming efficiency. However, if the higher program voltage is applied to the control gate electrode, a program current and power consumption may increase. In addition, a higher bias voltage may be applied to a source line to maintain the potential difference between a substrate and the drain region connected to the source line. However, if the higher bias voltage is applied to the source line, the higher bias voltage may affect an operation of adjacent memory cells, such that the adjacent memory cells may be programmed instead of the target memory cell.

### SUMMARY OF THE INVENTION

An example embodiment of the present invention is directed to a method of programming a nonvolatile memory device, including applying a first bias voltage to a gate electrode, applying a second bias voltage to a substrate to obtain a first voltage potential difference between the gate electrode and the substrate and applying a third bias voltage to a first impurity region to obtain a second voltage potential difference between the substrate and the first impurity region, the first and third bias voltages being positive and the second bias voltage being negative.

Another example embodiment of the present invention is directed to a nonvolatile memory device, including a gate electrode receiving a first bias voltage, a substrate receiving a second bias voltage, the first and second bias voltages forming a first voltage potential difference between the gate electrode and the substrate and a first impurity region receiving a third bias voltage, the second and third bias voltages forming a second voltage potential difference between the first impurity region and the substrate, the first and third bias voltages being positive and the second bias voltage being negative.

Another example embodiment of the present invention is directed to a method of driving a nonvolatile memory device which may enhance programming efficiency without substantially increasing a program current.

Another example embodiment of the present invention is directed to a nonvolatile memory device which may reduce or prevent a disturbance between adjacent memory cells using a negative back bias voltage.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a cross-section of a conventional silicon-oxide-nitride-oxide-silicon (SONOS) nonvolatile memory device.

FIG. 2 is a cross-section of a SONOS nonvolatile memory device including a local charge trap layer according to an example embodiment of the present invention.

FIG. 3 is an equivalent circuit diagram of the local SONOS nonvolatile memory device of FIG. 2 if a conventional bias voltage of 0 V is applied to a semiconductor substrate according to another example embodiment of the present invention.

FIG. 4 is an equivalent circuit diagram of the local SONOS nonvolatile memory device of FIG. 2 if a back bias voltage of −1.0 V is applied to a semiconductor substrate according to another example embodiment of the present invention.

FIG. 5 is a graph illustrating a threshold voltage of the local SONOS nonvolatile memory device of FIG. 2 under first and second test conditions according to another example embodiment of the present invention.

FIG. 6 is a graph illustrating degradation and current distribution of the local SONOS nonvolatile memory device if erased under a conventional test condition.

FIG. 7 is a graph illustrating degradation and current distribution of the local SONOS nonvolatile memory device if erased under a test condition according to another example embodiment of the present invention.

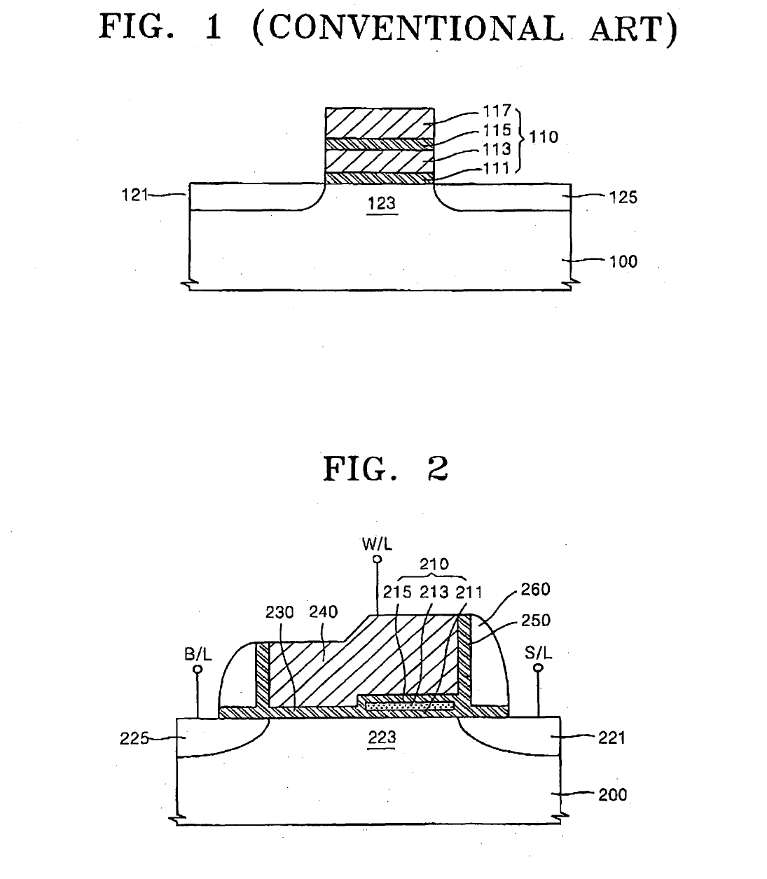

### DETAILED DESCRIPTION OF EXAMPLE EMBODIMENTS OF THE PRESENT INVENTION

Detailed illustrative example embodiments of the present invention are disclosed herein. However, specific structural and functional details disclosed herein are merely representative for purposes of describing example embodiments of the present invention. Example embodiments of the present invention may, however, be embodied in many alternate forms and should not be construed as limited to the embodiments set forth herein.

Accordingly, while example embodiments of the invention are susceptible to various modifications and alternative forms, specific embodiments thereof are shown by way of example in the drawings and will herein be described in detail. It should be understood, however, that there is no intent to limit example embodiments of the invention to the particular forms disclosed, but conversely, example embodiments of the invention are to cover all modifications, equivalents, and alternatives falling within the spirit and scope of the invention. Like numbers may refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. Conversely, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 2 is a cross-section of a silicon-oxide-nitride-oxide-silicon (SONOS) nonvolatile memory device including a local charge trap layer according to an example embodiment of the present invention.

In the example embodiment of FIG. 2, the SONOS nonvolatile memory device may include a first impurity region 221 for a source and a second impurity region 225 for a drain, which may be separated from each other, in a semiconductor substrate 200. A channel region 223 may be interposed between the first and second impurity regions 221 and 225. In an example, the first and second impurity regions 221 and 225 may have a conductivity opposite to that of the semiconductor substrate 200 and may include, for example, n-type impurity regions. The first and second impurity regions 221 and 225 may have a lightly doped drain (LDD) structure. A source line S/L may be connected to the first impurity region 221, and a bit line B/L may be connected to the second impurity region 225.

In the example embodiment of FIG. 2, a charge storage layer 210 may be formed on the channel region 223 adjacent to the first impurity region 221. The charge storage layer 210 may include a tunneling insulating layer 211, a charge trap layer 213 and a charge blocking layer 215 stacked sequentially. In an example, the tunneling insulating layer 211 may include a silicon oxide layer formed by thermal oxidation and/or a higher-k dielectric oxide layer (e.g., formed by chemical vapor deposition (CVD) and/or atomic layer deposition (ALD)). In another example, the charge trap layer 213 may include a silicon nitride layer and/or a boron nitride layer formed by the CVD and/or the ALD. In a further example, the charge trap layer 213 may include a nanodot and/or a nanocrystal. The charge blocking layer 215 may include a silicon oxide layer formed by the thermal oxidation and/or by CVD.

In the example embodiment of FIG. 2, a gate insulating layer 230 may be formed on the channel region 223 adjacent to the second impurity region 225. In an example, the gate insulating layer 230 may include a silicon oxide layer formed by thermal oxidation and/or by CVD. The control gate electrode 240 may be formed on the gate insulating layer 230 and the charge storage layer 210. In an example, the control gate electrode 240 may include a polysilicon layer and/or a doped polysilicon layer. The control gate electrode 240 may be connected to a word line W/L.

In the example embodiment of FIG. 2, an insulating spacer 250 and a conductive spacer 260 may be formed on a sidewall of the gate electrode 240 and on the semiconductor substrate 200. In an example, the insulating spacer 250 may include a silicon oxide layer formed by thermal oxidation and/or CVD. In another example, the conductive spacer 260 may include a polysilicon layer and/or a doped polysilicon layer. In an example, the conductive spacer 260 may not overlap the channel region 223, but may overlap the first and second impurity regions 221 and 225.

In the example embodiment of FIG. 2, in order to program the SONOS nonvolatile memory device, a given positive voltage may be applied to the control gate electrode 240, and a given bias voltage may be applied to the second impurity region 225 connected to the bit line B/L, and to the first impurity region 221 connected to the source line S/L, thereby creating a potential difference between the first and second impurity regions 221 and 225. Hot electrons, which may be generated in the channel region 223 near the first impurity region 221, may be injected into the charge trap layer 213 via the tunneling insulating layer 211. Consequently, a threshold voltage of the SONOS nonvolatile memory device may be increased.

In the example embodiment of FIG. 2, in order to erase the SONOS nonvolatile memory device, a given negative bias voltage may be applied to the control gate electrode 240, and a given bias voltage may be applied to the first and second impurity regions 221 and 225, thereby creating a potential difference between the first and second impurity regions 221 and 225. Holes, which may be generated in the channel region 223 near the first impurity region 221, may be injected into the charge trap layer 213 via the tunneling insulating layer 211. The injected holes may be recombined with the hot electrons trapped in the charge trap layer 213, thereby lowering the threshold voltage of the SONOS nonvolatile memory device.

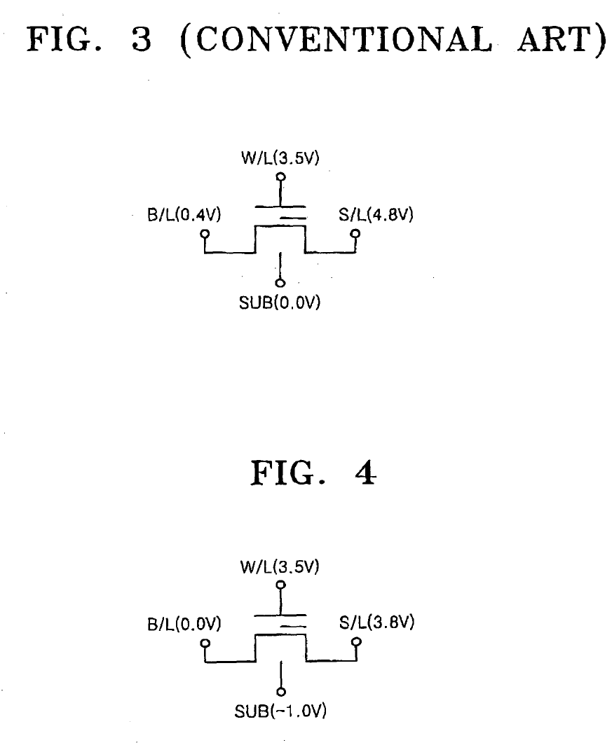

A programming operation of the local SONOS nonvolatile memory device of FIG. 2 will now be described in more detail with reference to the example embodiments of FIGS. 3 and 4. FIGS. 3 and 4 are equivalent circuit diagrams of the local SONOS nonvolatile memory device of FIG. 2. Specifically, FIG. 3 is an equivalent circuit diagram of the local SONOS nonvolatile memory device of FIG. 2 if a conventional bias voltage of 0 V (e.g., a ground voltage) is applied to the semiconductor substrate SUB 200 according to another example embodiment of the present invention. FIG. 4 is an equivalent circuit diagram of the local SONOS nonvolatile memory device of FIG. 2 if a back bias voltage of −1.0 V is applied to the semiconductor substrate SUB according to another example embodiment of the present invention.

Referring to conventional FIG. 3, a positive bias voltage (e.g., 3.5 V) may be applied to the word line W/L connected to the control gate electrode 240, and a bias voltage (e.g., 0.0 V) may be applied to the semiconductor substrate SUB to program the local SONOS nonvolatile memory device. In addition, a positive bias voltage (e.g., 0.4 V) may be applied to the bit line B/L, which may be connected to the second impurity region 225, and a positive bias voltage (e.g., 4.8 V) may be applied to the source line S/L, which may be connected to the first impurity region 221.

In the example embodiment of FIG. 4, a positive bias voltage (e.g., 3.5 V) may be applied to the word line W/L, and a negative bias voltage (e.g., −1 V) may be applied to the semiconductor substrate SUB to program the local SONOS nonvolatile memory device. In addition, a bias voltage (e.g., 0.0 V) may be applied to the bit line B/L, and a positive bias voltage (e.g., 3.8 V) may be applied to the source line S/L.

In the example embodiment of FIG. 4, in an example, if a equal program voltage (e.g., 3.5 V) is applied to the control gate electrode 240, a higher potential difference (e.g., 4.5 V) may be created between the semiconductor substrate SUB and the word line W/L in the case of FIG. 4. In contrast, a lesser potential difference (e.g., 3.5 V) may be created between the semiconductor substrate SUB and the word line W/L in the case of FIG. 3. Therefore, if the negative bias voltage is applied to the semiconductor substrate SUB as the substrate voltage, a programming efficiency of the local SONOS nonvolatile memory device may be enhanced without increasing a program voltage.

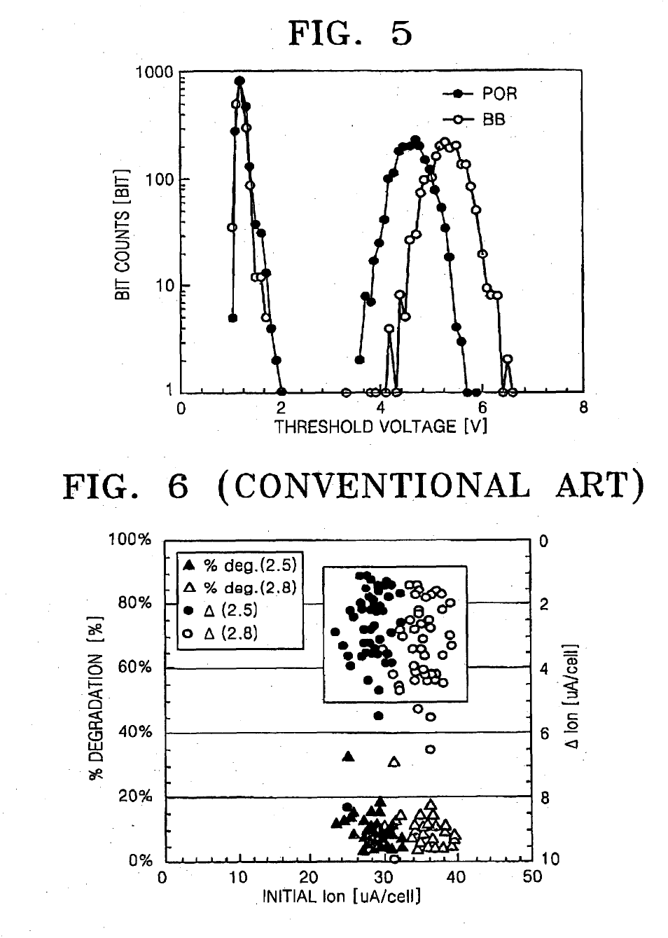

FIG. 5 is a graph illustrating a threshold voltage of the local SONOS nonvolatile memory device of FIG. 2 under first and second test conditions according to another example embodiment of the present invention. The first test condition may be indicated by BB in Table 1 (below), where a negative bias voltage may be applied to the semiconductor substrate SUB according to another example embodiment of the present invention. The threshold voltage of the local SONOS nonvolatile memory device of FIG. 2 under the second test condition may be indicated by POR in Table 1 (below), where a conventional bias voltage may be applied to the substrate voltage SUB. Accordingly, Table 1 (below) may illustrate threshold voltages and program currents of the local SONOS nonvolatile memory device under the first test condition BB and the second (e.g., conventional) test condition POR.

TABLE 1

| | Vth, ini | Vth, on | Vth, off | Δ Vth |
|---|---|---|---|---|
| POR | 3.0 | 1.2 | 4.6 | 3.4 |
| BB | 2.2 | 1.2 | 5.3 | 4.1 |

Referring to Table 1, Vth,ini may denote a threshold voltage measured at the time of fab-out, Vth,on may denote a threshold voltage measured when the local SONOS nonvolatile memory device is erased, and Vth,off may denote a threshold voltage measured when the local SONOS nonvolatile memory device is programmed. In addition, Δ Vth may denote a difference between the threshold voltages of the nonvolatile memory device when erased and when programmed (e.g., Vth,off−Vth,on).

In the example embodiment of FIG. 5 and with reference to Table 1, the threshold voltage difference Δ Vth of the local SONOS nonvolatile memory device under the first test condition BB may be 4.1 V while the threshold voltage difference Δ Vth of the local SONOS nonvolatile memory device under the second test condition POR may be 3.4 V. Therefore, if an equal program current is applied to the local SONOS nonvolatile memory device under both the first and second test conditions BB and POR, a sensing window may be approximately 21 percent higher or longer in the local SONOS nonvolatile memory device under the first test condition BB.

In the example embodiment of FIG. 5, the same potential difference (e.g., 4.8 V) may be created between the semiconductor substrate SUB and the source line S/L in the local SONOS nonvolatile memory device under both of the first and second test conditions BB and POR. However, because a negative bias voltage (e.g., −1.0 V) may be applied to the semiconductor substrate SUB in the local SONOS nonvolatile memory device under the first test condition BB, a lower positive bias voltage (e.g., 3.8 V) may be applied to the source line S/L while a higher positive bias voltage (e.g., 4.8 V) may be applied to the source line S/L in the local SONOS nonvolatile memory device under the second test condition POR. Therefore, the local SONOS nonvolatile memory device under the first test condition BB may have a lower bias voltage applied to the source line S/L than the local SONOS nonvolatile memory device under the second test condition POR. Consequently, band-to-band tunneling (BTBT) in the second impurity region 225 may be reduced, which, in turn, may reduce a “disturbance” (e.g., inadvertently affect a non-selected or non-targeted memory cell) between adjacent memory cells.

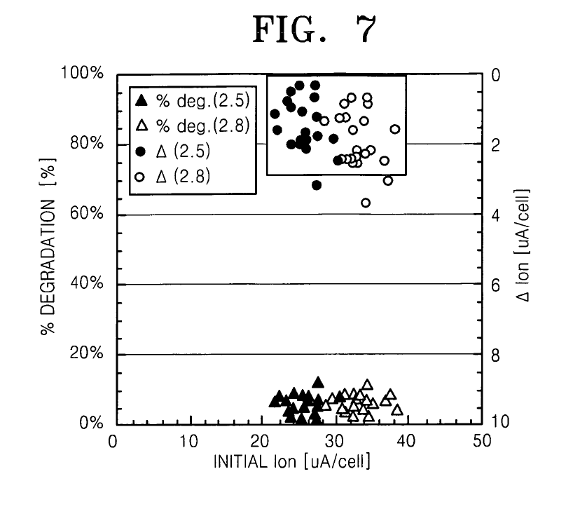

FIG. 6 is a graph illustrating degradation and current distribution of the local SONOS nonvolatile memory device if erased under the first test condition POR (e.g., conventional test conditions). FIG. 7 is a graph illustrating degradation and current distribution of the local SONOS nonvolatile memory device if erased under the second test condition BB according to another example embodiment of the present invention. As shown in FIGS. 6 and 7, the local SONOS nonvolatile memory device under the first test condition BB (e.g., in FIG. 7) may illustrate an improved distribution of Δ Ion and a reduction of approximately 10% in degradation, compared with the local SONOS nonvolatile memory device under the second test condition POR.

Table 2 (below) illustrates a threshold voltage and a program current of a node voltage of each node in the local SONOS nonvolatile memory device of the example embodiment of FIG. 2 according to another example embodiment of the present invention. Referring to Table 2, Vwl may denote a voltage applied to the word line W/L, Vsl may denote a voltage applied to the source line S/L, Vbl may denote a voltage applied to the bit line B/L, and Vsub may denote the substrate voltage applied to the semiconductor substrate SUB. On_Vth may denote a threshold voltage of the local SONOS nonvolatile memory device when erased, and Off_Vth may denote a threshold voltage of the local SONOS nonvolatile memory device when programmed. Ipgm@On_Vth may denote a program current if the local SONOS nonvolatile memory device has the threshold voltage On_Vth, which may be obtained if the local SONOS nonvolatile memory device is erased (e.g., during an erasing or deletion operation). In the example of Table 2, an effective potential difference between the source line S/L and the semiconductor substrate SUB may be maintained at 4.8 V.

TABLE 2

| | Vwl/Vsl/Vbl/Vsub | On_Vth | Off_Vth | Ipgm@On_Vth |
|---|---|---|---|---|
| POR | 3.5/4.8/0.4/0.0[V] | 1.27[V] | 4.50[V] | 49.2[μA]@1.27 |
| BB-I | 3.5/4.3/0.4/−0.5[V] | 1.27[V] | 5.36[V] | 58.7[μA]@1.27 |
| BB-II | 3.5/3.8/0.0/−1.0[V] | 1.27[V] | 5.30[V] | 52.4[μA]@1.27 |
| BB-III | 3.5/2.8/0.0/−2.0[V] | 1.27[V] | 4.54[V] | 38.6[μA]6@1.27 |

In the example of Table 2, a voltage condition of each node in the local SONOS nonvolatile memory device under the second test condition (e.g., conventional conditions) POR in which a conventional bias voltage of 0 V is applied to the semiconductor substrate SUB may be listed. A voltage condition of each node in the local SONOS non-volatile memory device in a number of first test conditions BB-I, BB-II and BB-III, each according to an example embodiment of the present invention, may also be listed in Table 2. BB-I, BB-II and BB-III may indicate different examples of first test conditions in which different negative bias voltages may be applied to the semiconductor substrate SUB of the local SONOS nonvolatile memory device.

In the example of Table 2, a stable program current Ipgm may be applied to the local SONOS nonvolatile memory device under the second test condition POR and also under the first test conditions BB-I, BB-II and BB-III. For example, referring to test condition BB-II, with reference to the example of Table 2, 3.5 V, 3.8 V, 0.0 V, and −1.0 V may be applied to the word line W/L, the source line S/L, the bit line B/L, and the semiconductor substrate SUB, respectively, in the local SONOS nonvolatile memory device under the first test condition BB-II. Therefore, in an example, the sensing window of the local SONOS nonvolatile memory device under the first test condition BB-II may be approximately 20 percent higher or longer than that of the local SONOS nonvolatile memory device under the second test condition POR in which 3.5 V, 4.8 V, 0.4 V, and 0.0 V may be applied to the word line W/L, the source line S/L, the bit line B/L and the semiconductor substrate SUB, respectively.

Likewise, in the example of Table 2, if the local SONOS nonvolatile memory device is under the first test condition BB-I, in which 3.5 V, 3.8 V, 0.0 V, and −0.5 V are applied to the word line W/L, the source line S/L, the bit line B/L, and the semiconductor substrate SUB, respectively, a sensing window may be increased as compared to the second test condition POR. However, because the program current Ipgm may increase (e.g., by 20 percent) if the local SONOS nonvolatile memory device is under the first test conditions BB-I as compared with the second test condition POR, a current consumption of the local SONOS non-volatile memory device employing the first test condition BB-I may likewise increase. In another example, if the local SONOS nonvolatile memory device is under the first test condition BB-III, in which 3.5 V, 2.8 V, 0.0 V, and −2.0 V are applied to the word line W/L, the source line S/L, the bit line B/L, and the semiconductor substrate SUB, respectively, the sensing window may increase to a lesser degree (e.g., as compared to the first test condition BB-I).

Generally, as will be appreciated from a review of the example of Table 2 as the negative bias voltage is applied as the substrate voltage increases, the threshold voltage of the local SONOS nonvolatile memory device may be reduced, thereby reducing a sensing margin. Therefore, an increase of the negative bias voltage may be limited. Thus, a balance may be achieved between increasing the sensing window without substantially increasing the program current and also reducing or prevent “disturbance” (e.g., an unintended affect on neighbouring or adjacent memory cells) between memory cells. For example, 3.5 V, 3.8 V, 0.0 V, −1.0 V may be applied to the word line W/L, the source line S/L, the bit line B/L, and the semiconductor substrate SUB, respectively.

In another example embodiment of the present invention, if a negative bias voltage is applied to a semiconductor substrate included in a local SONOS non-volatile memory device, a potential difference between a word line and the semiconductor substrate may be increased without substantially increasing a program current, and an effective potential difference between a source line and the semiconductor substrate may thereby be maintained. Therefore, a sensing window may be increased without substantially reducing programming efficiency, and a disturbance between adjacent memory cells may be prevented.

Example embodiments of the present invention being thus described, it will be obvious that the same may be varied in many ways. For example, while the example embodiments of the present invention list particular examples of voltages (e.g., bias voltages, program voltages, potential difference voltages, positive bias voltages, negative bias voltages, etc.), it is understood that such numerical listings are given for purposes of example only, and are not intended to limit the scope of the present invention.

Such variations are not to be regarded as a departure from the spirit and scope of example embodiments of the present invention, and all such modifications as would be obvious to one skilled in the art are intended to be included within the scope of the following claims.

What is claimed is:

1. A method of programming a nonvolatile memory device, comprising:
applying a first bias voltage to a gate electrode;
applying a second bias voltage to a substrate to obtain a first voltage potential difference between the gate electrode and the substrate; and
applying a third bias voltage to a first impurity region to obtain a second voltage potential difference between the substrate and the first impurity region, the first and third bias voltages being positive and the second bias voltage being negative.

2. The method of claim 1, wherein the first voltage potential difference is 4.5 V and the second bias voltage is −1.0 V.

3. The method of claim 1, wherein the second potential difference is 4.8 V.

4. The method of claim 1, wherein the first impurity region is one of a plurality of impurity regions.

5. The method of claim 1, wherein the second potential difference is greater than the first potential difference.

6. The method of claim 1, wherein the second bias voltage is −1.0 V.

7. The method of claim 5, wherein the first potential difference is 4.5 V, and the second potential difference is 4.8 V.

8. The method of claim 1, wherein the gate electrode is connected to a word line, the first impurity region is connected to a source line a second impurity region is connected to a bit line.

9. The method of claim 1, wherein a fourth bias voltage is applied to a second impurity region, the fourth bias voltage being greater than the second bias voltage and smaller than the third bias voltage.

10. The method of claim 9, wherein the fourth bias voltage is one of 0 V and a ground voltage.

11. The method of claim 9, wherein the second impurity region is floating.

12. A nonvolatile memory device, comprising:
a gate electrode receiving a first bias voltage;
a substrate receiving a second bias voltage, the first and second bias voltages forming a first voltage potential difference between the gate electrode and the substrate; and
a first impurity region receiving a third bias voltage, the second and third bias voltages forming a second voltage potential difference between the first impurity region and the substrate, the first and third bias voltages being positive and the second bias voltage being negative.

13. The nonvolatile memory device of claim 12, further comprising:
a second impurity region formed in the substrate along with the first impurity region, each of the first and second impurity regions having a first conductivity, the substrate having a second conductivity and the first and second conductivities not being the same;
a channel region formed in a portion of the substrate between the first and second impurity regions;
a charge storage layer formed on a first portion of the channel region in proximity to one of the first and second impurity regions, the charge storage layer including a tunneling insulating layer, a charge trap layer and a charge blocking layer;
a gate insulating layer formed on a second portion of the channel region; and
a gate electrode formed on the gate insulating layer and the charge storage layer.

14. The nonvolatile memory device of claim 12, wherein the second bias voltage is −1.0 V.

15. The device of claim 12, wherein the second potential difference is greater than the first potential difference.

16. The device of claim 15, wherein the first potential difference is 4.5 V, and the second potential difference is 4.8 V.

17. The device of claim 13, further comprising:
an insulating spacer and a conductive spacer formed on a sidewall of the gate electrode to overlap the first and second impurity regions without overlapping the channel region.

18. The device of claim 12, wherein the gate electrode is connected to a word line, the first impurity region is connected to a source line, and a second impurity region is connected to a bit line.

19. A method of programming the nonvolatile memory device of claim 12.
